(19) United States
(12) Patent Application Publication
(10) Pub. No.: US 2025/0113533 A1
(43) Pub. Date: Apr. 3, 2025

(54) SEMICONDUCTOR DEVICE AND POWER CONVERSION DEVICE

(71) Applicant: Mitsubishi Electric Corporation, Chiyoda-ku, Tokyo (JP)

(72) Inventor: Kazunari NAKATA, Tokyo (JP)

(73) Assignee: Mitsubishi Electric Corporation, Chiyoda-ku, Tokyo (JP)

(21) Appl. No.: 18/832,489

(22) PCT Filed: Mar. 2, 2023
(86) PCT No.: PCT/JP2023/007772

§ 371 Date: Jul. 23, 2024

(30) Foreign Application Priority Data
Mar. 30, 2022 (JP) 2022-056620

(51) Int. Cl. H10D 30/66; H10D 62/832; H10D 64/27

(52) U.S. Cl. CPC H10D 30/668; H10D 62/8325; H10D 64/513; H10D 64/514

(57) ABSTRACT

A semiconductor device includes an insulating film covering a reference surface of a semiconductor substrate and an electrode. The insulating film includes a first upper surface and a protrusion part protruding from the first upper surface corresponding to the reference surface of the semiconductor substrate and at least a part of the electrode protruding from the reference surface, respectively. A distance from the reference surface of the semiconductor substrate to a connection part connecting the first upper surface of the insulating film and a surface of the protrusion part is equal to or larger than a distance from the reference surface of the semiconductor substrate to a second upper surface of the electrode.

### TECHNICAL FIELD

The present disclosure relates to a semiconductor device and a power conversion device.

### BACKGROUND ART

Silicon carbide (SiC) has higher withstand voltage and lower resistance than silicon (Si), and is excellent in heat resistance. In order to use a semiconductor device with high withstand voltage and low loss under high temperature environment, proposed is a power semiconductor device such as a metal oxide semiconductor field effect transistor (MOSFET) and an insulated gate bipolar transistor (IGBT) which are made of SiC, for example.

Proposed in these SiC semiconductor devices is a technique of downsizing a semiconductor device by increasing a current density of the semiconductor device or reducing the number of the semiconductor devices by using a parasitic diode (for example, Patent Documents 1 and 2). Manufacturing cost of the SiC semiconductor device is reduced by the above technique, thus the SiC semiconductor device is considered to be used for various components such as inverter component, for example, in the future.

### PRIOR ART DOCUMENTS

### Patent Document(s)

Patent Document 1: Japanese Patent Application Laid-Open No. 2019-75411
Patent Document 2: Japanese Patent Application Laid-Open No. 2020-13916

### SUMMARY

### Problem to be Solved by the Invention

A semiconductor device further having a small size and high efficiency is developed with high insulation breakdown electrical field of SiC in the SiC semiconductor device. However, positions to which stress is applied is increased in assembly by increase of the number of wirings for ensuring current capacity, and stress is increased by temperature rise in an operation in accordance with increase of a current density in power conduction. As a result, damage occurs in an electrode such as a gate electrode of the semiconductor device, for example, thus there is a problem that reliability of the semiconductor device is deteriorated.

The present disclosure is therefore has been made to solve problems as described above, and it is an object of the present disclosure to provide a technique capable of increasing reliability of a semiconductor device.

### Means to Solve the Problem

A semiconductor device according to the present disclosure includes: a semiconductor substrate; an electrode, at least a part of which protrudes to an upper side from a reference surface of the semiconductor substrate; and an insulating film covering the reference surface of the semiconductor substrate and the electrode, wherein the insulating film includes a first upper surface and a protrusion part protruding from the first upper surface corresponding to the reference surface of the semiconductor substrate and the at least the part of the electrode protruding from the reference surface, respectively, and a distance from the reference surface of the semiconductor substrate to a connection part connecting the first upper surface of the insulating film and a surface of the protrusion part is equal to or larger than a distance from the reference surface of the semiconductor substrate to a second upper surface of the electrode.

### Effects of the Invention

According to the present disclosure, the distance from the reference surface of the semiconductor substrate to the connection part is equal to or larger than the distance from the reference surface of the semiconductor substrate to the second upper surface of the electrode. According to such a configuration, reliability of the semiconductor device can be increased.

### BRIEF DESCRIPTION OF DRAWINGS

FIG. 1 A top view illustrating a whole configuration of an SiC semiconductor device according to an embodiment 1.

FIG. 2 A cross-sectional view illustrating a configuration of an SiC semiconductor device according to the embodiment 1.

FIG. 3 A flow chart illustrating a manufacturing process of the SiC semiconductor device according to the embodiment 1.

FIG. 4 A cross-sectional view illustrating the manufacturing process of the SiC semiconductor device according to the embodiment 1.

FIG. 5 A cross-sectional view illustrating the manufacturing process of the SiC semiconductor device according to the embodiment 1.

FIG. 6 A cross-sectional view illustrating the manufacturing process of the SiC semiconductor device according to the embodiment 1.

FIG. 7 A cross-sectional view illustrating the manufacturing process of the SiC semiconductor device according to the embodiment 1.

FIG. 8 A cross-sectional view illustrating the manufacturing process of the SiC semiconductor device according to the embodiment 1.

FIG. 9 A cross-sectional view illustrating the manufacturing process of the SiC semiconductor device according to the embodiment 1.

FIG. 10 A cross-sectional view illustrating the manufacturing process of the SiC semiconductor device according to the embodiment 1.

FIG. 11 A cross-sectional view illustrating the manufacturing process of the SiC semiconductor device according to the embodiment 1.

FIG. 12 A cross-sectional view illustrating the configuration of the SiC semiconductor device according to the embodiment 1.

FIG. 13 A cross-sectional view illustrating an SEM image of the configuration of the SiC semiconductor device according to the embodiment 1.

FIG. 14 A cross-sectional view illustrating an implementation example of the SiC semiconductor device according to the embodiment 1.

FIG. 15 A diagram illustrating a result of a test.

FIG. 16 A cross-sectional view illustrating a configuration of an SiC semiconductor device according to an embodiment 2.

FIG. 17 A flow chart illustrating a manufacturing process of the SiC semiconductor device according to the embodiment 2.

FIG. 18 A cross-sectional view illustrating the manufacturing process of the SiC semiconductor device according to the embodiment 2.

FIG. 19 A cross-sectional view illustrating the manufacturing process of the SiC semiconductor device according to the embodiment 2.

FIG. 20 A cross-sectional view illustrating the manufacturing process of the SiC semiconductor device according to the embodiment 2.

FIG. 21 A cross-sectional view illustrating the manufacturing process of the SiC semiconductor device according to the embodiment 2.

FIG. 22 A cross-sectional view illustrating the manufacturing process of the SiC semiconductor device according to the embodiment 2.

FIG. 23 A cross-sectional view illustrating the manufacturing process of the SiC semiconductor device according to the embodiment 2.

FIG. 24 A cross-sectional view illustrating the manufacturing process of the SiC semiconductor device according to the embodiment 2.

FIG. 25 A cross-sectional view illustrating the manufacturing process of the SiC semiconductor device according to the embodiment 2.

FIG. 26 A cross-sectional view illustrating the manufacturing process of the SiC semiconductor device according to the embodiment 2.

FIG. 27 A cross-sectional view illustrating the manufacturing process of the SiC semiconductor device according to the embodiment 2.

FIG. 28 A cross-sectional view illustrating the manufacturing process of the SiC semiconductor device according to the embodiment 2.

FIG. 29 A cross-sectional view illustrating the manufacturing process of the SiC semiconductor device according to the embodiment 2.

FIG. 30 A cross-sectional view illustrating the manufacturing process of the SiC semiconductor device according to the embodiment 2.

FIG. 31 A cross-sectional view illustrating the manufacturing process of the SiC semiconductor device according to the embodiment 2.

FIG. 32 A cross-sectional view illustrating the manufacturing process of the SiC semiconductor device according to the embodiment 2.

FIG. 33 A cross-sectional view illustrating the configuration of the SiC semiconductor device according to the embodiment 2.

FIG. 34 A diagram illustrating a result of a test.

FIG. 35 A cross-sectional view illustrating a configuration of an SiC semiconductor device according to an embodiment 3.

FIG. 36 A cross-sectional view illustrating the configuration of the SiC semiconductor device according to the embodiment 3.

FIG. 37 A cross-sectional view illustrating the configuration of the SiC semiconductor device according to the embodiment 3.

FIG. 38 A block diagram illustrating a configuration of a power conversion system to which a power conversion device according to an embodiment 4 is applied.

### DESCRIPTION OF EMBODIMENT(S)

An embodiment is described hereinafter with reference to the accompanying diagrams. Features described in each embodiment hereinafter are exemplifications, thus are not always necessary. In the description hereinafter, the same or similar reference numerals will be assigned to the similar constituent elements in the plurality of embodiments, and different constituent elements are mainly described. In the description hereinafter, a specific position and direction such as “upper”, “lower”, “left”, “right”, “front”, and “rear”, for example, necessarily need not coincide with a position and direction in an actual implementation.

### Embodiment 1

In the description hereinafter, a semiconductor device according to the present embodiment 1 is an SiC semiconductor device including silicon carbide (SiC) as wide bandgap semiconductor. However, a material of the semiconductor device according to the present embodiment 1 may be normal silicon (Si) or wide bandgap semiconductor other than silicon carbide (SiC). The wide bandgap semiconductor other than silicon carbide (SiC) is gallium nitride and diamond, for example.

When a material of the semiconductor device is the wide bandgap semiconductor, the semiconductor device can be used with high withstand voltage and low loss under high temperature environment. Particularly, SiC has higher insulation breakdown electrical field than Si, thus a withstand voltage layer (drift layer, for example) for achieving the same withstand voltage, and an amount of impurity doping of the withstand voltage layer can be increased, thus ON resistance, for example, can be reduced.

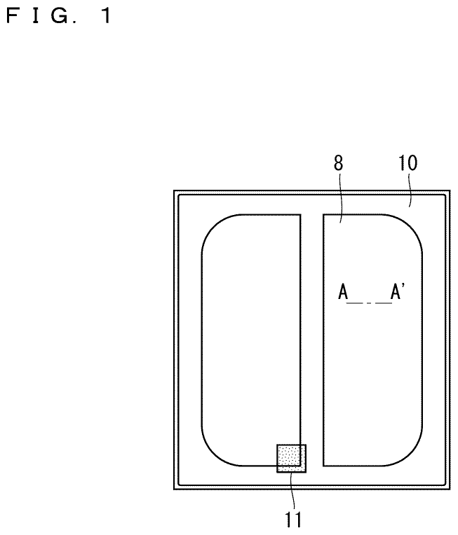

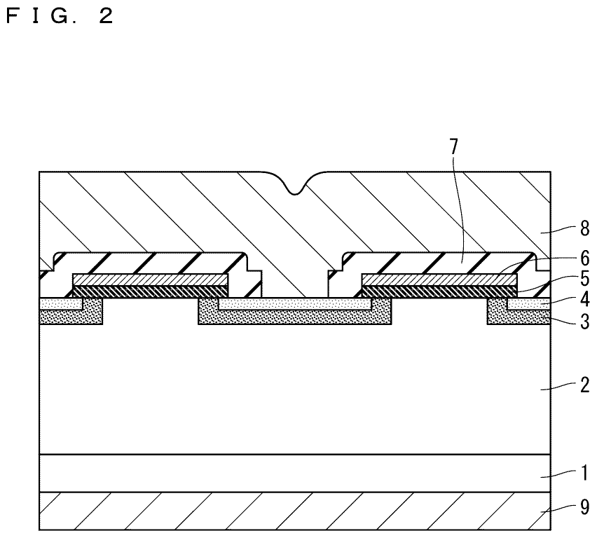

FIG. 1 is a top view illustrating a whole configuration of the SiC semiconductor device according to the present embodiment 1, and FIG. 2 is a cross-sectional view illustrating a configuration of the SiC semiconductor device according to the embodiment 1 along an A-A′ line in FIG. 1.

The SiC semiconductor device includes an insulation protective film provided to an outer surrounding insulating region 10 in FIG. 1, a gate connection part 11, and a configuration in FIG. 2 surrounded by the outer surrounding insulating region 10 and electrically connected to the gate connection part 11.

The configuration in FIG. 2 includes an SiC substrate 1 as an n-type semiconductor substrate, an n-type drift layer 2, a p-type base region 3, an n-type source region 4, a gate insulating film 5, a gate electrode 6 as an electrode, an interlayer insulating film 7 as an insulating film, a source electrode 8, and a drain electrode 9.

The gate connection part 11 in FIG. 1 is electrically connected to the gate electrode 6 in FIG. 2. The above n type and p type may be replaced with the p type and n type, respectively.

The SiC semiconductor device according to the present embodiment 1 is a MOSFET having a planar gate structure, and FIG. 2 illustrates a major part of a cell structure of the SiC semiconductor device. In a whole configuration of the actual SiC semiconductor device, the cell configuration illustrated in FIG. 1 is repetitively provided in a planar direction of the SiC substrate 1. The SiC semiconductor device according to the present disclosure may be a MOSFET, an IGBT, a reverse conducting-IGBT (RC-IGBT), a Schottky barrier diode (SBD), or a PN junction diode (PND) each having a trench gate structure. Described in an embodiment 2 is an example that the SiC semiconductor device according to the present disclosure is a MOSFET having a trench gate structure.

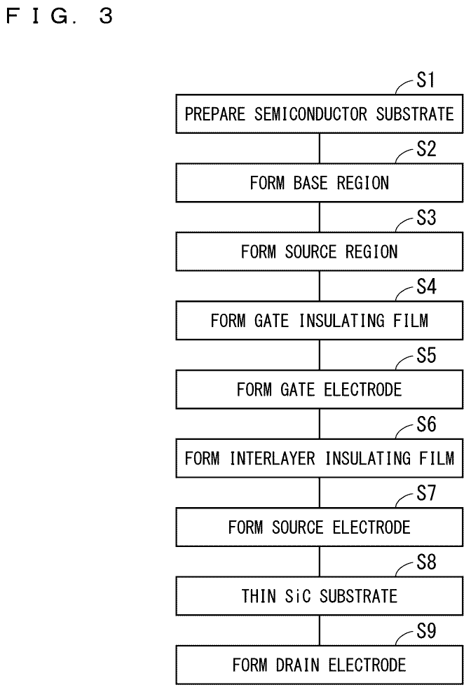

FIG. 3 is a flow chart illustrating a manufacturing process of the SiC semiconductor device according to the present embodiment 1, and the SiC semiconductor device is manufactured in this order.

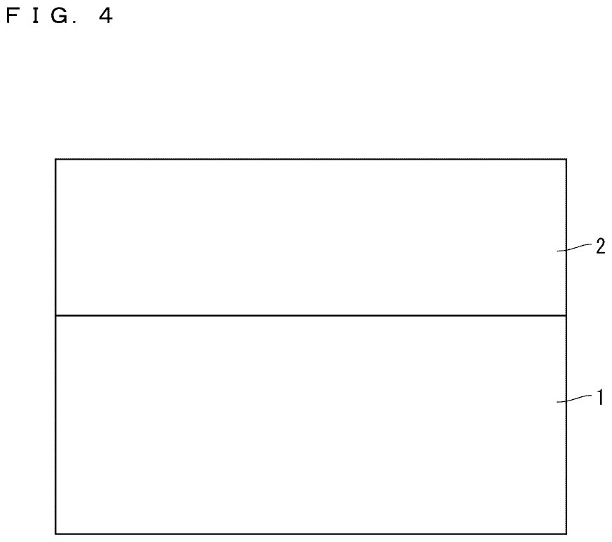

In a process of preparing a semiconductor substrate in Step S1, as illustrated in FIG. 4, the drift layer 2 including SiC is formed as an epitaxial film on a first main surface (described as a front surface hereinafter) of the SiC substrate 1.

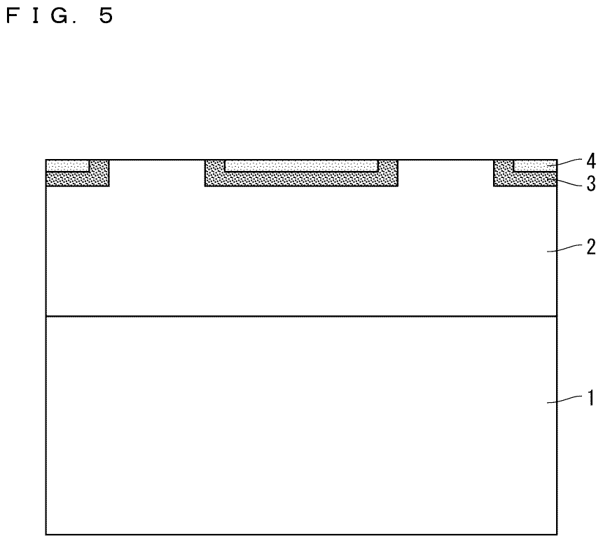

Next, in a process of forming a base region in Step S2, as illustrated in FIG. 5, a p-type impurity is selectively ion-implanted after a mask (not shown) made up of a resist, for example, is formed on the n-type drift layer 2, and the base region 3 is selectively formed on an upper portion of the drift layer 2. The p-type impurity is boron (B) and aluminum (Al), for example.

Subsequently, in a process of forming a source region in Step S3, as illustrated in FIG. 5, an n-type impurity is selectively ion-implanted after a mask (not shown) made up of a resist, for example, is formed on the p-type base region 3, and the source region 4 is selectively formed on an upper portion of the base region 3. The n-type impurity is phosphorus (P) and nitrogen (N), for example.

Then, a thermal treatment is performed on the SiC substrate 1 at a high temperature by a thermal treatment apparatus (not shown) after the ion implantation is performed as described above to activate the base region 3 and the source region 4. Accordingly, p-type and n-type ions implanted into the base region 3 and the source region 4 are electrically activated.

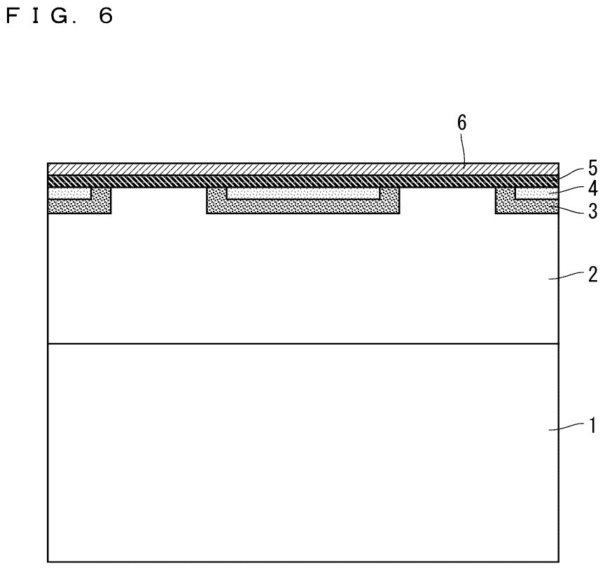

Next, in a process of forming agate insulating film in Step S4, as illustrated in FIG. 6, the gate insulating film 5 is formed on the drift layer 2, the base region 3, and the source region 4 by a thermal oxidation method or a deposition method such as chemical vapor deposition.

Then, in a process of forming a gate electrode in Step S5, the gate electrode 6 is formed on the gate insulating film 5. The gate electrode 6 may be formed by depositing polycrystalline Si or polysilicon using chemical vapor deposition, for example, or when an operation of the SiC semiconductor device at a higher speed is desired, the gate electrode 6 may be formed by depositing a tungsten film or a tungsten silicide (WSiₓ) film.

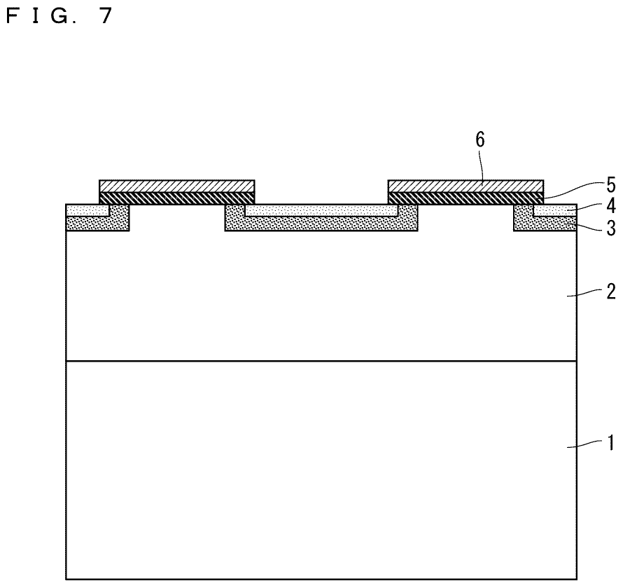

Subsequently, as illustrated in FIG. 7, patterning is performed on the gate insulating film 5 and the gate electrode 6 using a photolithography technique and a dry etching or wet etching technique. Patterning is performed on the gate electrode 6 so that a pair of base regions 3 and a pair of source regions 4 are located on a lower side of both end portions of the gate electrode 6, and a part of the drift layer 2 located between the pair of base regions 3 is located on a lower side of a center portion of the gate electrode 6.

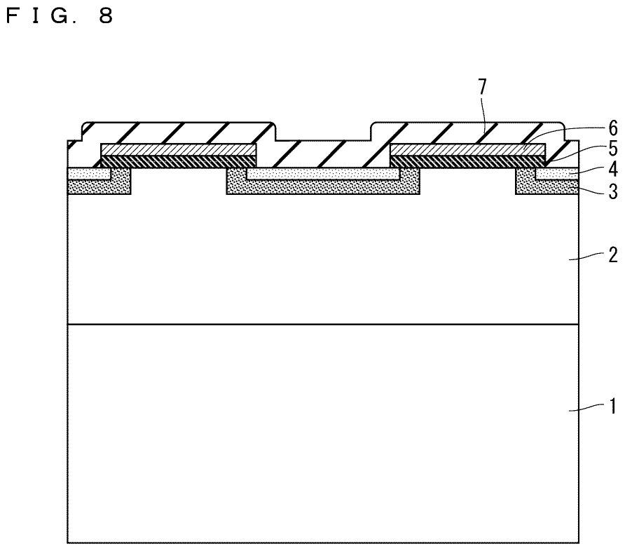

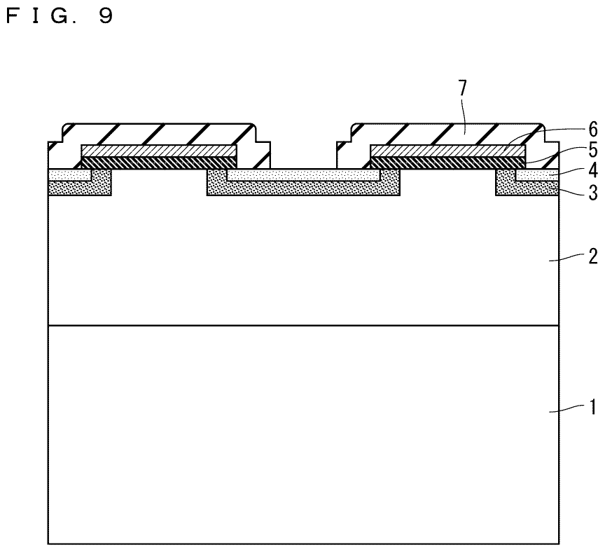

Next, in a process of forming an interlayer insulating film in Step S6, as illustrated in FIG. 8, a film made of tetra ethoxy silane (TEOS), for example, is formed as the interlayer insulating film 7 using a chemical vapor deposition (CVD) method, for example. Next, as illustrated in FIG. 9, patterning is performed on the interlayer insulating film 7 using a photolithography technique and a dry etching or wet etching technique to expose a part of the source region 4.

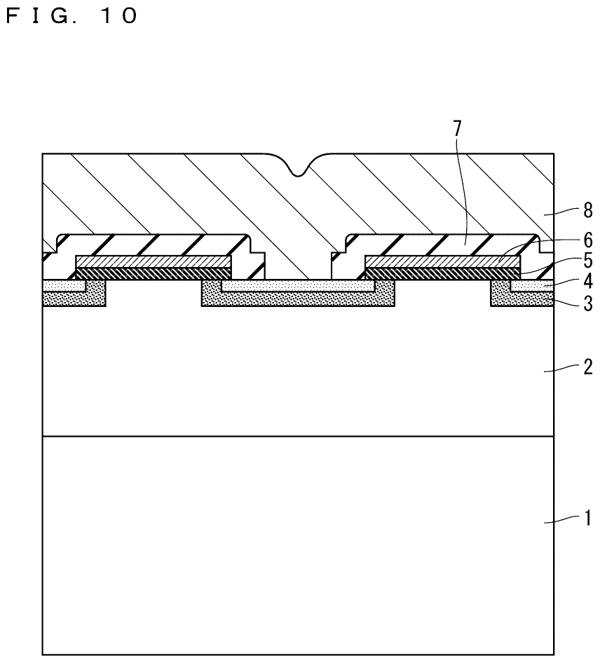

Next, in a process of forming a source electrode in Step S7, as illustrated in FIG. 10, the source electrode 8 is formed on the source region 4 and the interlayer insulating film 7. The source electrode 8 is formed by appropriately forming a barrier metal made of titanium or a titanium compound such as titanium nitride (TiN), for example, on a film made of aluminum or aluminum alloy made of aluminum and silicon, or nickel, for example. Although not illustrated in the diagrams, subsequently, patterning of the source electrode 8 is performed using a photolithography technique and a dry etching or wet etching technique.

Subsequently, the insulation protective film is formed in the outer surrounding insulating region 10 in FIG. 1. A material of the insulation protective film is polyimide resin or silicone resin, for example. A photolithography technique is preferably used for forming the insulation protective film to accurately form a shape of the insulation protective film, and an etching technique may be used together. The method of forming the insulation protective film is not limited thereto, however, a screen printing technique or a pattern coating technique, for example, may be used.

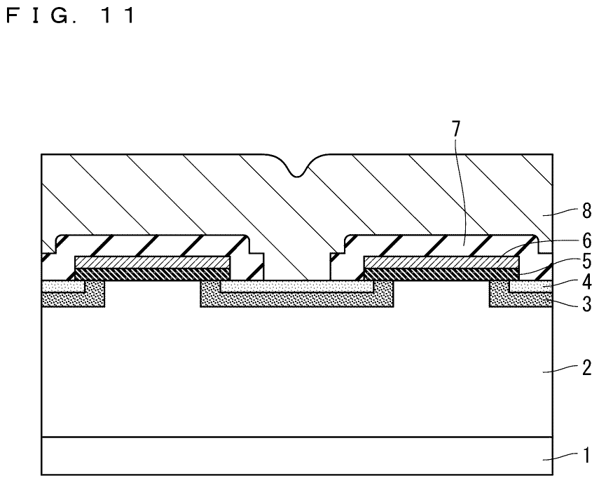

Next, the SiC substrate 1 is thinned by performing mechanical processing on a second main surface (described as a back surface hereinafter) of the SiC substrate 1 using an abrasive wheel in a process of thinning an SiC substrate in Step S8, and the SiC substrate 1 is thinned as illustrated in FIG. 11.

Subsequently, the drain electrode 9 is formed on the back surface of the SiC substrate 1 in a process of forming a drain electrode in Step S9. The SiC semiconductor device in FIG. 2 is thereby completed. The drain electrode 9 is formed by forming a nickel film having a thickness of appropriately 600 nm, for example, appropriately using a sputtering method, for example. When a surface of nickel is oxidized, wettability between solder alloy and nickel is deteriorated, and a bonding state in a chip bonding is deteriorated. Thus, the drain electrode 9 made up of a lamination film of a nickel film and a protective film may be formed by forming the protective film made of metal having low reactivity such as gold or silver on the surface of nickel.

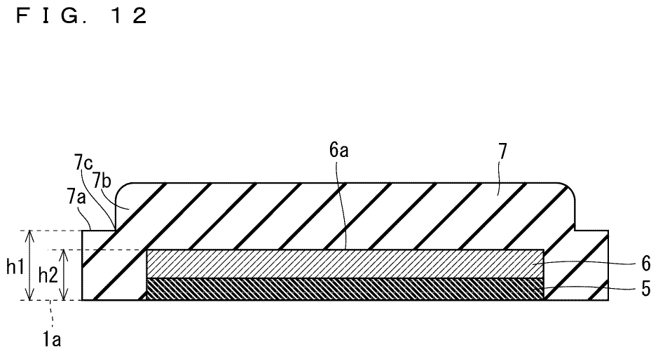

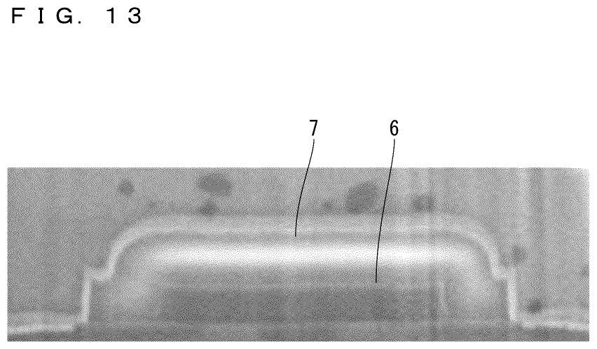

FIG. 12 is a cross-sectional view illustrating the gate electrode 6 and constituent elements around the gate electrode 6 in the configuration in FIG. 2, and FIG. 13 is a cross-sectional view illustrating an image of the configuration in FIG. 12 taken with a scanning electron microscope (SEM). FIG. 12 illustrates an upper surface of the SiC substrate 1 as a reference surface Ta.

The gate electrode 6 is wholly disposed on an upper side of the reference surface 1a of the SiC substrate 1, and the interlayer insulating film 7 covers the reference surface 1a of the SiC substrate 1 and the gate electrode 6. The interlayer insulating film 7 includes a first upper surface 7a and a protrusion part 7b protruding from the first upper surface 7a, and the first upper surface 7a and the protrusion part 7b correspond to the reference surface 1a of the SiC substrate 1 and the gate electrode 6 protruding from the reference surface 1a, respectively.

FIG. 12 illustrates a connection part 7c connecting the first upper surface 7a of the interlayer insulating film 7 and a surface of the protrusion part 7b, and also illustrates a distance h1 from the reference surface 1a of the SiC substrate 1 to the connection part 7c. FIG. 12 also illustrates a distance h2 from the reference surface 1a of the SiC substrate 1 to a second upper surface 6a of the gate electrode 6. The distance h1 is equal to or larger than the distance h2 in the present embodiment 1. That is to say, a ratio (h1/h2) of the distance h1 to the distance h2 is equal or larger than one.

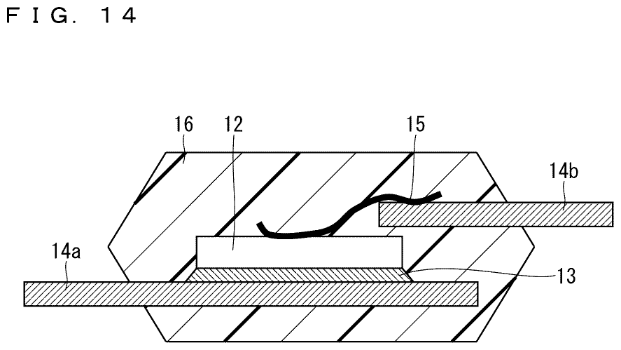

FIG. 14 is a cross-sectional view illustrating an implementation example of the SiC semiconductor device according to the present embodiment 1. FIG. 14 illustrates the SiC semiconductor device in FIG. 2 as an SiC semiconductor device 12. As illustrated in FIG. 14, a back surface of the SiC semiconductor device 12 is connected to a lead frame 14a via a solder 13, and a front surface of the SiC semiconductor device 12 is connected to the lead frame 14b via a wire 15. The SiC semiconductor device 12 and a portion around the SiC semiconductor device 12 are covered by mold resin 16.

An assembly test of the SiC semiconductor device is performed on such a configuration in FIG. 14. In the assembly test, a load of a tool in wire-bonding the wire 15 is one and half times as large as a standard load to evaluate accelerated deterioration in which stress repetitively occurs.

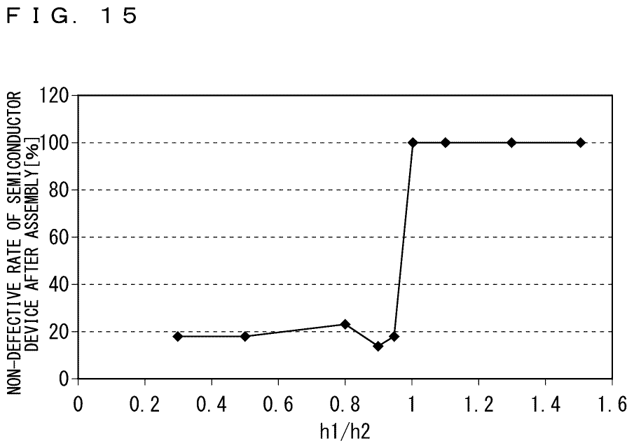

FIG. 15 is a diagram illustrating a result of the assembly test. A lateral axis indicates the ratio (h1/h2) of the distance h1 to the distance h2, and a vertical axis indicates a non-defective rate of the SiC semiconductor device determined to be a non-defective product in the assembly test. As illustrated in FIG. 15, when the ratio (h1/h2) is equal to or larger than one, the non-defective rate of the SiC semiconductor device after assembly can be increased. As described above, in the SiC semiconductor device according to the present embodiment 1, the distance h1 is equal to or larger than the distance h2, and the ratio (h1/h2) is equal to or larger than one, thus the non-defective rate of the SiC semiconductor device can be increased, and reliability can be thereby increased.

In the above description, the electrode covered by the interlayer insulating film 7 is the gate electrode 6, however, the configuration is not limited thereto. For example, the electrode covered by the interlayer insulating film 7 may be a dummy electrode used as a dummy of the gate electrode 6. The same applies to the embodiment 2 described hereinafter, for example.

### Embodiment 2

The SiC semiconductor device according to the embodiment 1 is the semiconductor device having the planar gate structure, however, an SiC semiconductor device according to the present embodiment 2 is a semiconductor device having a trench gate structure. A top view illustrating a whole configuration of the SiC semiconductor device according to the present embodiment 2 is similar to a top view (FIG. 1) illustrating the whole configuration of the SiC semiconductor device according to the embodiment 1.

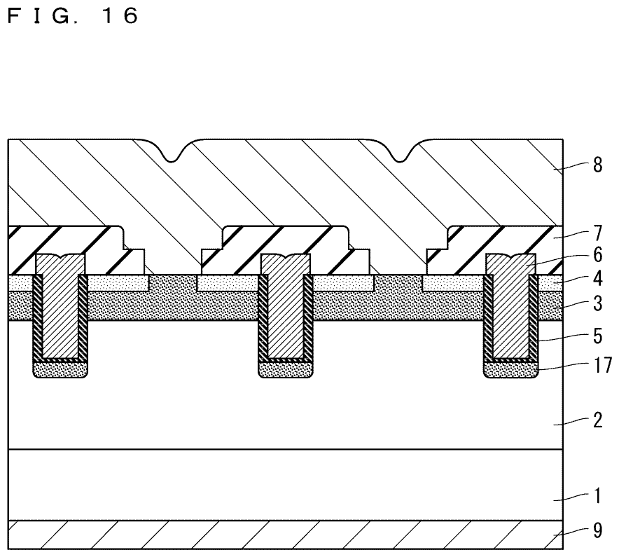

FIG. 16 is a cross-sectional view illustrating a configuration of the SiC semiconductor device according to the embodiment 2 along the A-A′ line in FIG. 1. A configuration in FIG. 16 includes the SiC substrate 1 as the n-type semiconductor substrate, the n-type drift layer 2, the p-type base region 3, the n-type source region 4, the gate insulating film 5, the gate electrode 6 as the electrode, the interlayer insulating film 7 as the insulating film, the source electrode 8, the drain electrode 9, and a p-type bottom part base region 17.

The gate connection part 11 in FIG. 1 is electrically connected to the gate electrode 6 in FIG. 16. The above n type and p type may be replaced with the p type and n type, respectively. FIG. 16 illustrates three trench gate structures, however, the number of trench gate structures is not limited thereto. In a whole configuration of the actual SiC semiconductor device, an optional number of trench gate structures illustrated in FIG. 16 are repetitively provided in a planar direction of the SiC substrate 1.

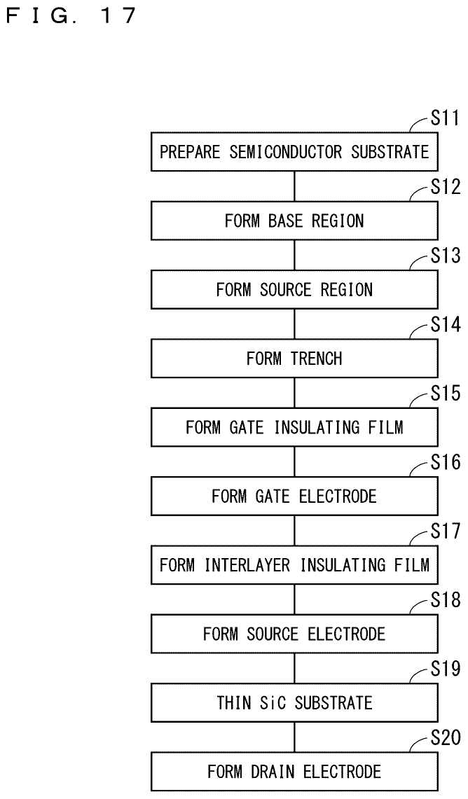

FIG. 17 is a flow chart illustrating a manufacturing process of the SiC semiconductor device according to the present embodiment 2, and the SiC semiconductor device is manufactured in this order.

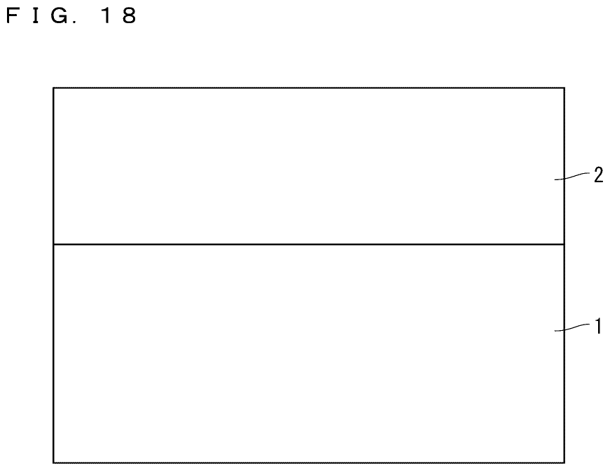

In a process of preparing a semiconductor substrate in Step S11, as illustrated in FIG. 18, the drift layer 2 including SiC is formed as an epitaxial film on the front surface of the SiC substrate 1.

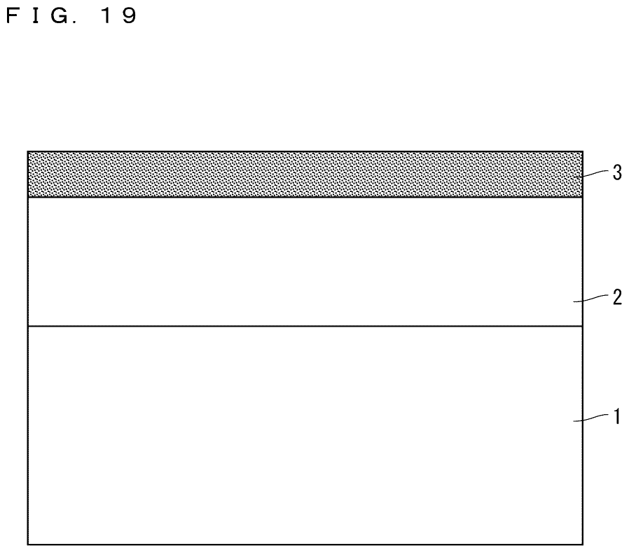

Next, in a process of forming the base region in Step S12, as illustrated in FIG. 19, the p-type impurity is selectively ion-implanted after the mask (not shown) made of the resist, for example, is formed on the n-type drift layer, and the base region 3 is selectively formed on the upper portion of the drift layer 2. The p-type impurity is boron (B) and aluminum (Al), for example.

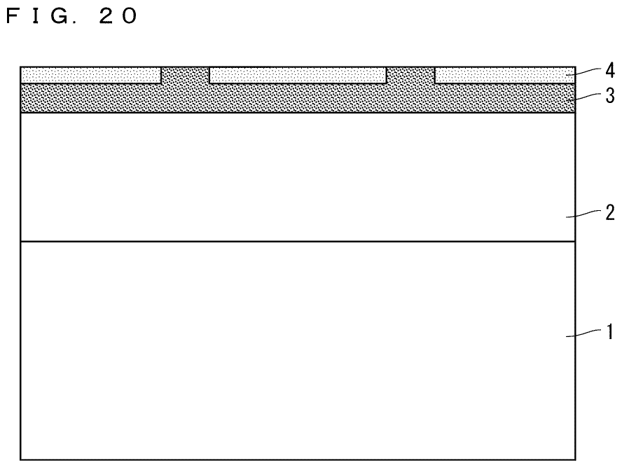

Subsequently, in a process of forming the source region in Step S13, as illustrated in FIG. 20, the n-type impurity is selectively ion-implanted after the mask (not shown) made up of the resist, for example, is formed on the p-type base region 3, and the source region 4 is selectively formed on the upper portion of the base region 3. The n-type impurity is phosphorus (P) and nitrogen (N), for example.

Then, a thermal treatment is performed on the SiC substrate 1 at a high temperature by the thermal treatment apparatus (not shown) after the ion implantation is performed as described above to activate the base region 3 and the source region 4. Accordingly, p-type and n-type ions implanted into the base region 3 and the source region 4 are electrically activated.

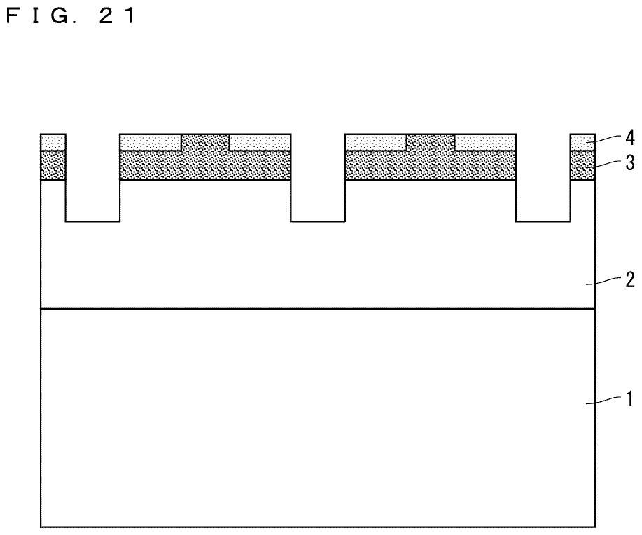

Next, in a process of forming a trench in Step S14, a trench as a groove illustrated in FIG. 21 is formed by dry etching using plasma, for example, after a mask (not shown) made up of a resist, for example, is formed to open a part of the source region 4. At this time, when a resist mask sufficiently withstanding the dry etching cannot be formed, it is sufficient that an oxide film made of TEOS as a material, for example, is formed on surfaces of the base region 3 and the source region 4 in FIG. 20 to perform dry etching using the oxide film as a mask. In this case, a deeper trench can be formed.

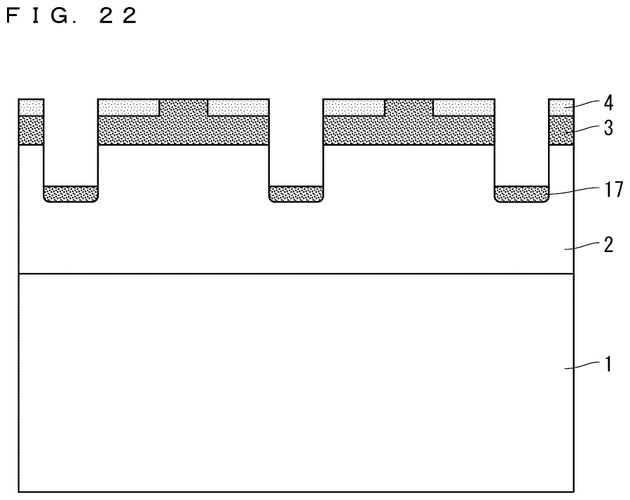

Subsequently, as illustrated in FIG. 22, a p-type impurity such as boron (B) or aluminum (Al) is ion-implanted into a bottom part of the trench to reduce an electrical field in a bottom part of the trench gate structure, thus the bottom part base region 17 is formed. When the reduction of the electrical field is not necessary, the bottom part base region 17 needs not be formed.

Then, in a process of forming agate insulating film in Step S15, the drift layer 2 is oxidized using a thermal oxidation method to remove plasma damage in forming the trench from the drift layer 2. An amount of oxidation is preferably large to remove the plasma damage, however, when the amount of oxidation is large, an impurity layer formed in the drift layer 2 is reduced. It can be confirmed from a measurement of leakage current between the gate electrode 6 and the source electrode 8 of a finished product that when a thermal oxide film having a thickness of 20 to 80 nm, preferably 30 to 70 nm is applied, the plasma damage is sufficiently removed from the drift layer 2 without substantially reducing the impurity layer.

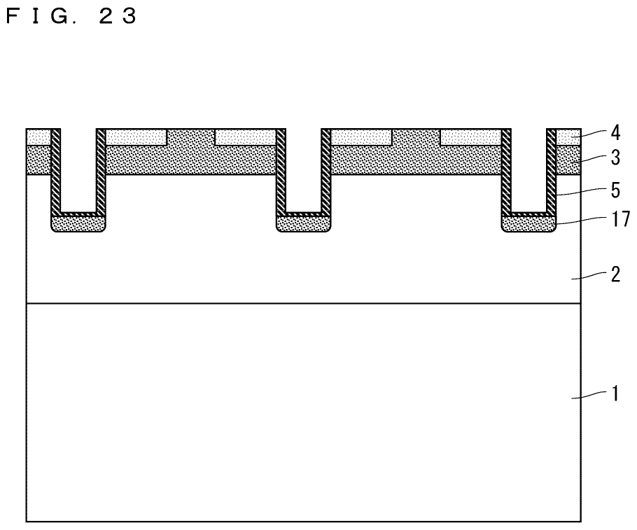

Subsequently, as illustrated in FIG. 23, the gate insulating film 5 is formed in a trench by a thermal oxidation method or a deposition method such as chemical vapor deposition. A thickness of the gate insulating film 5 on a side of a side surface of the trench is preferably equal to or larger than a thickness of the gate insulating film 5 on a side of a bottom surface of the trench, and is more preferably equal to or larger than 10% of the thickness of the gate insulating film 5 on the side of the bottom surface of the trench.

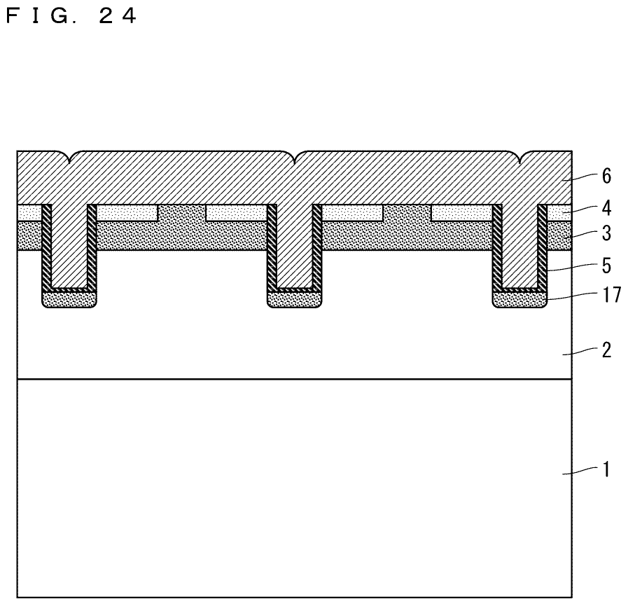

Then, in a process of forming a gate electrode in Step S16, the gate electrode 6 partially provided in the trench is formed as illustrated in FIG. 24. The gate electrode 6 may be formed by depositing polycrystalline Si or polysilicon using chemical vapor deposition, for example, or when an operation of the SiC semiconductor device at a higher speed is desired, the gate electrode 6 may be formed by depositing a tungsten film or a tungsten silicide (WSiₓ) film.

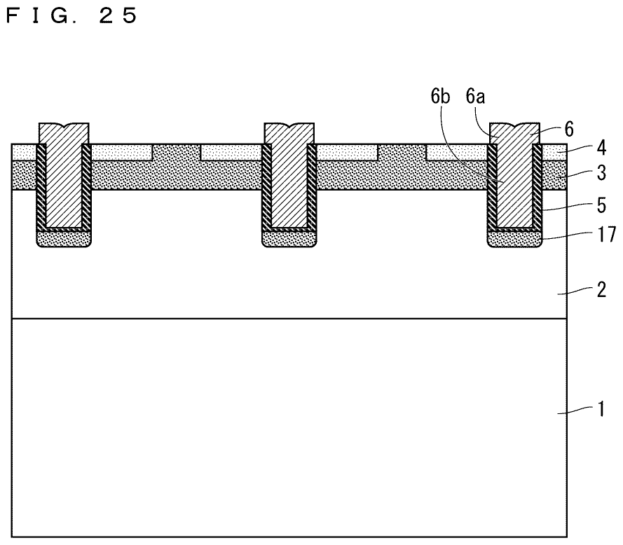

Next, as illustrated in FIG. 25, patterning is performed on the gate electrode 6 using a photolithography technique and a dry etching or wet etching technique. Isotropic etching is preferably used for patterning of the gate electrode 6. For example, etching with plasma including SF₆ is preferable when dry etching is applied, and etching with mixed acid including hydrofluoric acid and nitric acid is preferable when wet etching is applied.

In the present embodiment 2, as illustrated in FIG. 25, the gate electrode 6 includes a first electrode part 6b protruding a reference surface as an upper surface of the SiC substrate and a second electrode part 6c provided in the trench provided in the reference surface of the SiC substrate 1. In a planar direction of the SiC substrate 1, a width of the first electrode part 6b is larger than a width of the second electrode part 6c, and the gate electrode 6 has a T-like shape as a whole. According to such a configuration, a substantial contact area between the gate electrode 6 and the drift layer 2, the base region 3, and the source region 4 can be increased. Accordingly, when stress occurs in wiring or electrode bonding in assembly, a slide phenomenon of the gate electrode 6 such as a deviation of the gate electrode 6 in a longitudinal direction (front-back direction of a paper sheet of FIG. 25) can be suppressed. The inventor actually confirms in the assembly test by wiring that the slide phenomenon is suppressed according to the gate electrode 6 having the T-like shape described above.

Subsequently, an oxide layer which is not illustrated in the diagrams is formed on the surface of the gate electrode 6 by a thermal oxidation method. An oxidation temperature at this time is preferably 850 to 1050° C., for example, and is more preferably approximately 900 to 100° C.

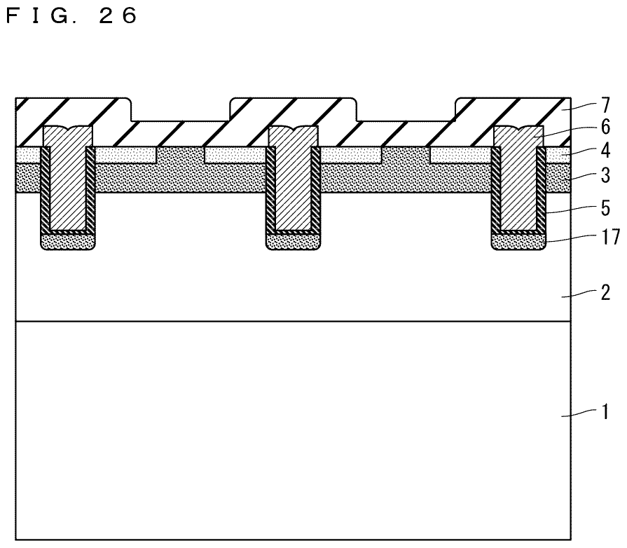

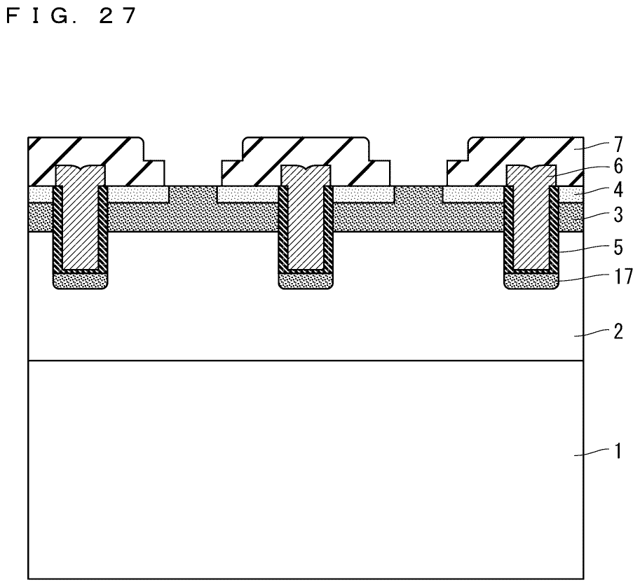

Next, in a process of forming an interlayer insulating film in Step S17, as illustrated in FIG. 26, a film made of TEOS, for example, is formed as the interlayer insulating film 7 using a chemical vapor deposition (CVD) method, for example. Next, as illustrated in FIG. 27, patterning is performed on the interlayer insulating film 7 using a photolithography technique and a dry etching or wet etching technique to expose a part of the base region 3 and the source region 4.

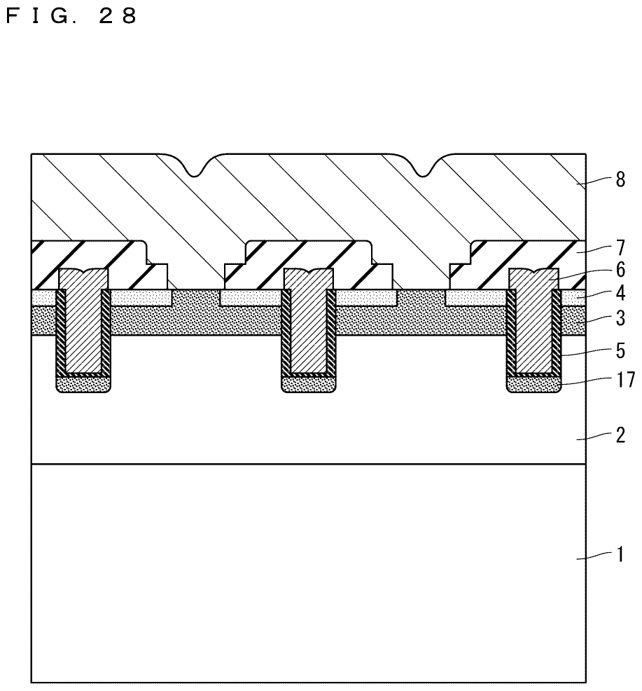

Next, in a process of forming a source electrode in Step S18, as illustrated in FIG. 28, the source electrode 8 is formed on the base region 3, the source region 4, and the interlayer insulating film 7. The source electrode 8 is formed by appropriately forming a barrier metal made of titanium or a titanium compound such as titanium nitride (TiN), for example, on a film made of aluminum or aluminum alloy made of aluminum and silicon, or nickel, for example. Although not illustrated in the diagrams, subsequently, patterning of the source electrode 8 is performed using a photolithography technique and a dry etching or wet etching technique.

Subsequently, the insulation protective film is formed in the outer surrounding insulating region 10 in FIG. 1. A material of the insulation protective film is polyimide resin or silicone resin, for example. A photolithography technique is preferably used for forming the insulation protective film to accurately form a shape of the insulation protective film, and an etching technique may be used together. The method of forming the insulation protective film is not limited thereto, however, a screen printing technique of a pattern coating technique, for example, may be used.

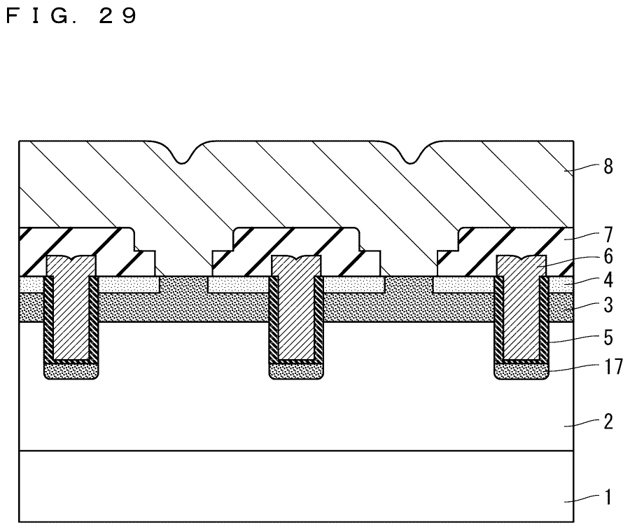

Next, the SiC substrate 1 is thinned by performing mechanical processing on the back surface of the SiC substrate 1 using the abrasive wheel in a process of thinning the SiC substrate in Step S19, and the SiC substrate 1 is thinned as illustrated in FIG. 29.

Subsequently, the drain electrode 9 is formed on the back surface of the SiC substrate 1 in a process of forming a drain electrode in Step S20. The SiC semiconductor device in FIG. 16 is thereby completed. The drain electrode 9 is formed by forming a nickel film having a thickness of appropriately 600 nm, for example, appropriately using a sputtering method, for example. When a surface of nickel is oxidized, wettability between solder alloy and nickel is deteriorated, and a bonding state in a chip bonding is deteriorated. Thus, the drain electrode 9 made up of a lamination film of a nickel film and a protective film may be formed by forming the protective film made of metal having low reactivity such as gold or silver on the surface of nickel.

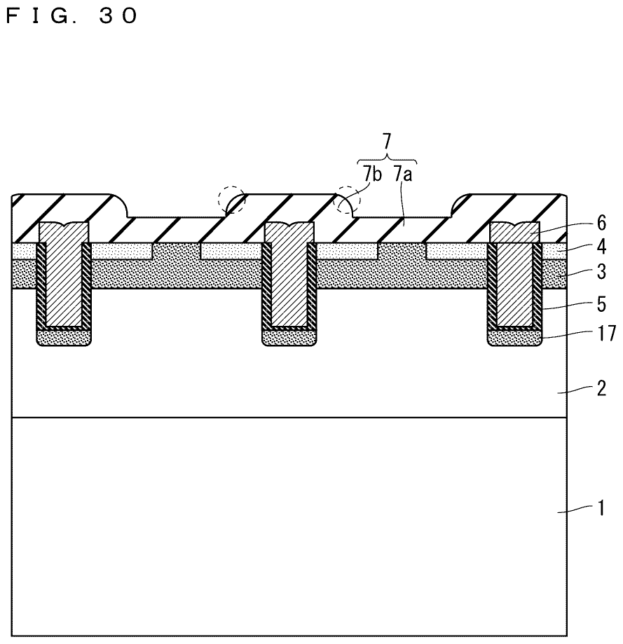

Another example that a process subsequent to the process of forming the interlayer insulating film in Step S17 is different from the example described above is described next. In this example, the interlayer insulating film 7 is a TEOS film or a spin-on-glass (SOG) film into which an impurity such as boron (B) or phosphorus (P) is introduced. When the interlayer insulating film 7 is the TEOS film, a thermal treatment is performed at a temperature of 700 to 900° C. after the TEOS film is formed, and when the interlayer insulating film 7 is the SOG film, a thermal treatment is performed at a temperature of 400 to 500° C. after the SOG film is formed. In this manner, when the thermal treatment corresponding to the material of the interlayer insulating film 7 is performed, a corner part assigned with a dashed circle of the protrusion part 7b protruding from the first upper surface 7a of the interlayer insulating film 7 illustrated in FIG. 30 can be rounded more than a corner part in FIG. 26.

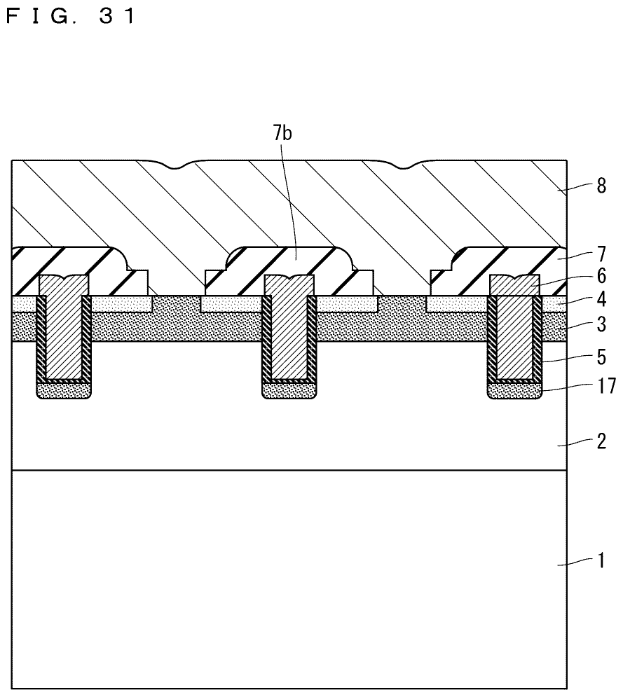

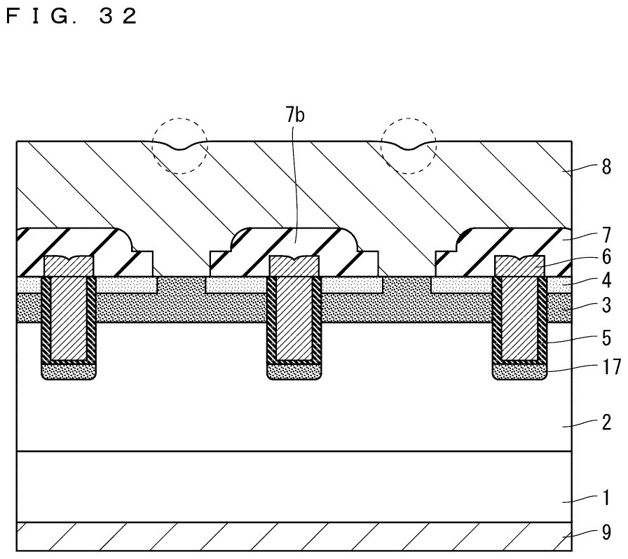

Subsequently, patterning is performed on the interlayer insulating film 7. Then, in a process of forming a source electrode in Step S18, as illustrated in FIG. 31, the source electrode 8 is formed on the base region 3, the source region 4, and the interlayer insulating film 7. Next, the SiC semiconductor device illustrated in FIG. 32 is completed through the process of thinning the SiC substrate in Step S19 and the process of forming the drain electrode in Step S20.

The corner part of the protrusion part 7b is rounded in the configuration in FIG. 32, thus a concave part assigned with a dashed circle in the upper surface of the source electrode 8 in FIG. 32 is shallower than the concave part in FIG. 16, thus the upper surface of the source electrode 8 is flattened. The inventor confirms that according to the configuration in FIG. 32 in which the upper surface of the source electrode 8 is flattened, a bonding strength between the wire after wiring and the source electrode 8 is increased more than that in the configuration in FIG. 16, and reliability of the SiC semiconductor device can be increased. This effect is effective in the configuration that the SiC semiconductor device 12 receives stress from various members such as the wire 15, the mold resin 16, and the lead frames 14a and 14b as illustrated in FIG. 14. Described hereinafter is the effect that reliability of the SiC semiconductor device is increased in the configuration in FIG. 32 in which the corner part of the protrusion part 7b is rounded and the upper surface of the source electrode 8 is flattened.

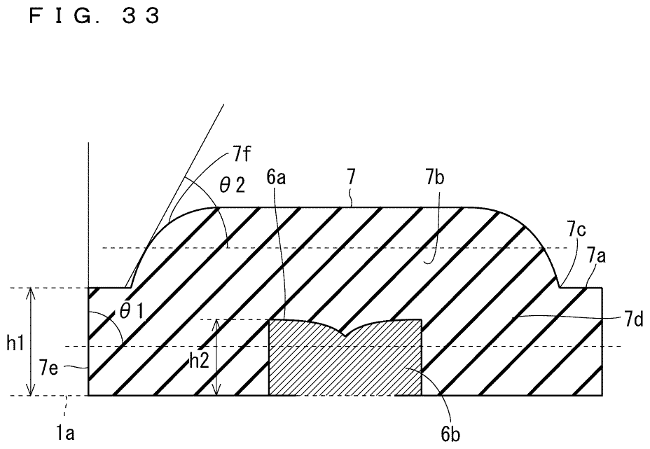

FIG. 33 is a cross-sectional view illustrating the gate electrode 6 and constituent elements around the gate electrode 6 in the configuration in FIG. 32. FIG. 32 illustrates the upper surface of the SiC substrate 1 as the reference surface 1a.

A first electrode part 6b of the gate electrode 6 protrudes from the reference surface 1a of the SiC substrate 1, and the interlayer insulating film 7 covers the reference surface 1a of the SiC substrate 1 and the gate electrode 6. The interlayer insulating film 7 includes the first upper surface 7a and the protrusion part 7b protruding from the first upper surface 7a, and the first upper surface 7a and the protrusion part 7b correspond to the reference surface 1a of the SiC substrate 1 and the gate electrode 6 protruding from the reference surface 1a, respectively.

FIG. 33 illustrates the connection part 7c connecting the first upper surface 7a of the interlayer insulating film 7 and the surface of the protrusion part 7b, and also illustrates the distance h1 from the reference surface 1a of the SiC substrate 1 to the connection part 7c. FIG. 33 also illustrates the distance h2 from the reference surface 1a of the SiC substrate 1 to the second upper surface 6a of the first electrode part 6b. In the present embodiment 2, in the manner similar to the embodiment 1, the distance h1 is equal to or larger than the distance h2, and the ratio (h1/h2) of the distance h1 to the distance h2 is equal or larger than one. Accordingly, in the present embodiment 2, the non-defective rate of the SiC semiconductor device after assembly can be increased in the manner similar to the embodiment 1, thus reliability of the SiC semiconductor device can be increased. The same applies to the configuration in FIG. 16 and the configuration in FIG. 32.

FIG. 33 illustrates an angle θ1 between the reference surface 1a of the SiC substrate 1 and a second side surface 7e of a lower part 7d of the interlayer insulating film 7 on a lower side of the first upper surface 7a. The angle θ1 in the example in FIG. 33 is an angle between the reference surface 1a of the SiC substrate 1 and the second side surface 7e in a position located in a half of a thickness of the lower part 7d.

FIG. 33 also illustrates an angle θ2 between the reference surface 1a of the SiC substrate 1 and a first side surface 7f of the protrusion part 7b of the interlayer insulating film 7. The first side surface 7f of the protrusion part 7b is a surface other than an upper surface of the protrusion part 7b, for example. The angle θ2 in the example in FIG. 33 is an angle between the reference surface 1a of the SiC substrate 1 and the first side surface 7f in a position located in a half of a thickness of the protrusion part 7b. In the configuration in FIG. 32 and FIG. 33, the angle θ1 is equal to or larger than the angle θ2, and the ratio (θ1/θ2) of the angle θ1 to the angle θ2 is equal to or larger than one.

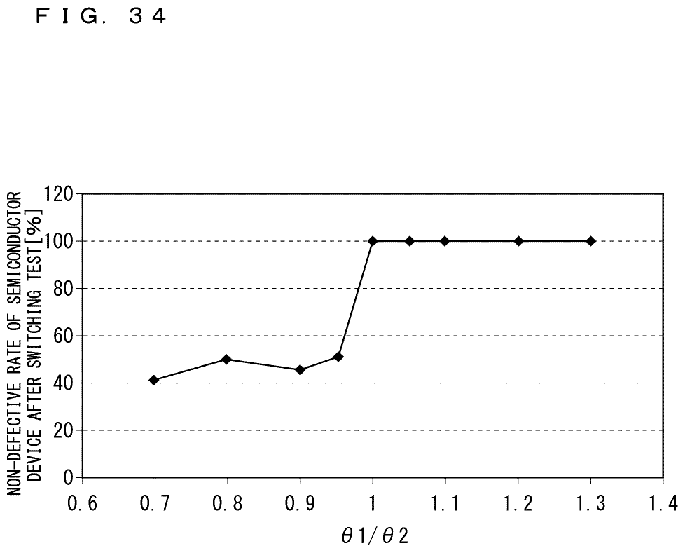

FIG. 34 is a graph illustrating anon-defective rate of the SiC semiconductor device after a switching test is performed on a cycle of ten thousands to evaluate accelerated deterioration in a configuration that the ratio (h1/h2) of the distance h1 to the distance h2 is one. Current twice rated current is applied in this test. A lateral axis indicates the ratio (θ1/θ2) of the angle θ1 to the angle θ2, and a vertical axis indicates a non-defective rate of the SiC semiconductor device determined to be a non-defective product in the switching test. As illustrated in FIG. 34, when the ratio (θ1/θ2) is equal to or larger than one, reliability of the SiC semiconductor device can be increased.

The state where the ratio (θ1/θ2) is equal to or larger than one is substantially the same as the state where the corner part of the protrusion part 7b is rounded. Thus, when the ratio (θ1/θ2) of the angle θ1 to the angle θ2 is equal to or larger than one, the upper surface of the source electrode 8 can be flattened, and the bonding strength between the wire 15 after wiring and the source electrode 8 can be increased. The configuration that the ratio (θ1/θ2) is equal to or larger than one can also be applied not only to the trench gate structure according to the present embodiment 2 but also to the planar structure according to the embodiment 1.

### Embodiment 3

In the present embodiment 3, the same reference sign is assigned to a constituent element similar to that in the embodiment 1 or the embodiment 2, and a detailed description thereof is omitted. A top view illustrating a whole configuration of the SiC semiconductor device according to the present embodiment 3 is similar to a top view (FIG. 1) illustrating the whole configuration of the SiC semiconductor device according to the embodiment 1 or the embodiment 2.

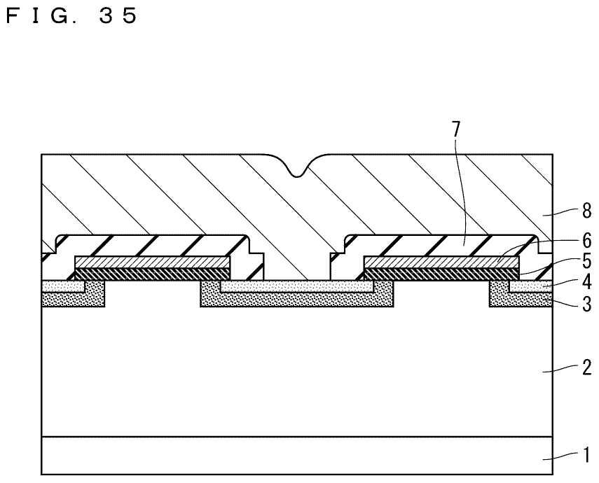

FIG. 35 is a cross-sectional view illustrating a configuration of the SiC semiconductor device according to the embodiment 3 along the A-A′ line in FIG. 1. A configuration in FIG. 35 includes the SiC substrate 1 as the n-type semiconductor substrate, the n-type drift layer 2, the p-type base region 3, the n-type source region 4, the gate insulating film 5, the gate electrode 6 as the electrode, the interlayer insulating film 7 as the insulating film, the source electrode 8, and the drain electrode 9.

The gate connection part 11 in FIG. 1 is electrically connected to the gate electrode 6 in FIG. 35. The above n type and p type may be replaced with the p type and n type, respectively.

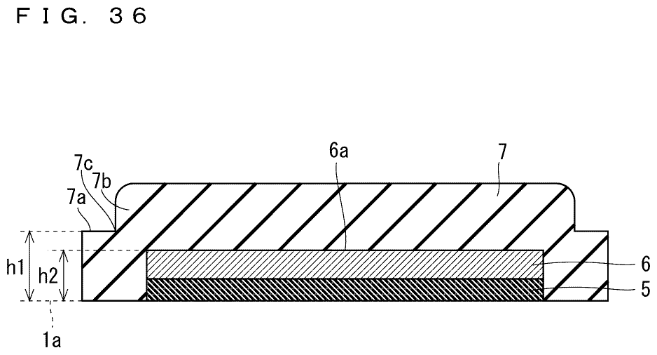

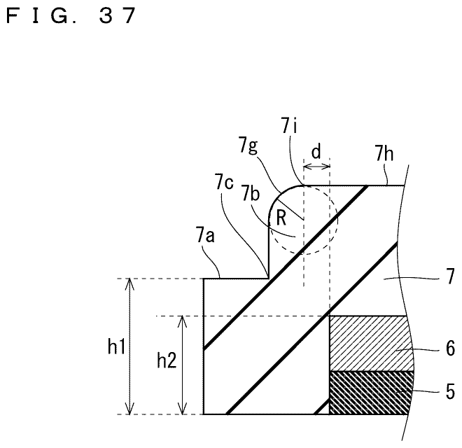

FIG. 36 is an enlarged view illustrating a mutual positional relationship between the gate insulating film 5, the gate electrode 6, and the interlayer insulating film 7 in FIG. 35. FIG. 37 is an enlarged view illustrating a mutual positional relationship between an end portion of the gate electrode 6 and the interlayer insulating film 7 in FIG. 36.

In the present embodiment 3, an outer edge of the protrusion part 7b of the interlayer insulating film 7 has a curved part 7g in a cross section. A connection part 7i between a straight part 7h and the curved part 7g in a cross section of the upper surface of the protrusion part 7b is located immediately above the end portion of the gate electrode 6 or immediately above an outer side of the end portion thereof. In other words, when the outer edge of the protrusion part 7b has a curvature radius R, and a distance from a center point of an arc of the curvature radius R and the end portion of the gate electrode 6 in a right-left direction of a paper sheet of FIG. 37 is d, d is equal to or larger than zero.

The SiC semiconductor device according to the present embodiment 3 is a MOSFET having a planar gate structure, but may also be a MOSFET, an IGBT, a reverse conducting-IGBT (RC-IGBT), a Schottky barrier diode (SBD), or a PN junction diode (PND) each having a trench gate structure.

A process of manufacturing the SiC semiconductor device according to the present embodiment 3 is similar to that illustrated in the flow chart in FIG. 3, and the SiC semiconductor device is manufactured in this order. The manufacturing process similar to that in the embodiment 1 is performed as illustrated in FIG. 4 to FIG. 7 in Step S1 to Step S5.

In the process of forming the interlayer insulating film in Step S6, as illustrated in FIG. 8, the film made of tetra ethoxy silane (TEOS) or a spin-on-glass (SOG) film, for example, is formed as the interlayer insulating film 7 using the chemical vapor deposition (CVD) method, for example. At this time, a boron concentration included in the interlayer insulating film 7 is equal to or smaller than 3 wt %. Accordingly, when the interlayer insulating film 7 is the TEOS film, a thermal treatment is performed at a temperature of 700 to 900° C. after the TEOS film is formed, thus the connection part 7i between the straight part 7h and the curved part 7g of the interlayer insulating film 7 can be located immediately above the outer side of the end portion of the gate electrode 6. In the similar manner, when the interlayer insulating film 7 is the SOG film, a thermal treatment is performed at a temperature of 400 to 500° C. after the SOG film is formed, thus the connection part 7i between the straight part 7h and the curved part 7g of the interlayer insulating film 7 can be located immediately above the outer side of the end portion of the gate electrode 6.

Then, as illustrated in FIG. 9, patterning is performed on the interlayer insulating film 7 using a photolithography technique and a dry etching or wet etching technique to expose a part of the source region 4.

Subsequently, the manufacturing process similar to that in the embodiment 1 is performed as illustrated in FIG. 10 to FIG. 11 in Step S7 to Step S9, thus the semiconductor device illustrated in FIG. 35 is completed.

According to the configuration described above, as illustrated in FIG. 15, the ratio (h1/h2) is equal or larger than one, and, the interlayer insulating film 7 covers the side surface of the gate electrode 6 in the assembly test with respect to the configuration in FIG. 14. Accordingly, force in aright-left direction applied to the gate electrode 6 in wiring can be reduced, thus a non-defective rate of the SiC semiconductor device after assembly can be increased. In the present embodiment 3, the connection part 7i between the straight part 7h and the curved part 7g in a cross section of the upper surface of the protrusion part 7b of the interlayer insulating film 7 is located immediately above the end portion of the gate electrode 6 or immediately above the outer side of the end portion thereof. Accordingly, force in an up-down direction applied to the gate electrode 6 in wiring can be reduced, thus the non-defective rate of the SiC semiconductor device after assembly can be increased, and the reliability can be thereby increased.

### Embodiment 4

The SiC semiconductor device according to any one of the embodiments 1 to 3 described above is applied to a power conversion device in the present embodiment 4. The power conversion device according to the present embodiment 4 is not limited to a specific power conversion device, however, described hereinafter is a case where the power conversion device according to the present embodiment 4 is applied to a three-phase inverter.

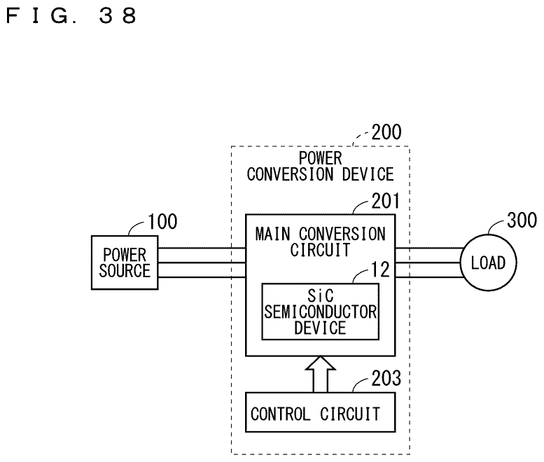

FIG. 38 is a block diagram schematically illustrating a configuration of a power conversion system to which a power conversion device 200 according to the present embodiment 4 is applied. This power conversion system includes a power source 100, a power conversion device 200, and a load 300.

The power source 100 is a direct current power source, and supplies direct current power to the power conversion device 200. The power source 100 can be made up of various power sources, thus may be made up of a direct current system, a solar battery, or a storage battery, for example, and may also be made up of a rectification circuit or an AC/DC converter each connected to an alternating current system. The power source 100 may also be made up of a DC/DC converter converting direct current power being output from a direct current system into predetermined power.

The power conversion device 200 is a three-phase inverter connected between the power source 100 and the load 300. The power conversion device 200 converts direct current power supplied from the power source 100 into alternating current power, and supplies the direct current power to the load 300. The power conversion device 200 includes a main conversion circuit 201 and a control circuit 203. The main conversion circuit 201 converts the direct current power which has been inputted into alternating current power, and outputs the alternating current power. The control circuit 203 outputs a control signal for controlling the main conversion circuit 201 to the main conversion circuit 201.

The load 300 is a three-phase electrical motor driven by the alternating current power supplied from the power conversion device 200. The load 300 is not for a specific purpose of usage, but is an electrical motor mounted on various types of electrical devices, thus is used as an electrical motor for a hybrid automobile, an electrical automobile, a railroad vehicle, an elevator, or an air-conditioning machine, for example.

Details of the power conversion device 200 are described hereinafter. The main conversion circuit 201 includes a switching element and a reflux diode (not shown). When the switching element is switched, the main conversion circuit 201 converts the direct current power supplied from the power source 100 into the alternating current power, and supplies the alternating current power to the load 300. Examples of a specific circuit configuration of the main conversion circuit 201 include various configurations, however, the main conversion circuit 201 according to the present embodiment 4 is a three-phase full-bridge circuit with two levels, and can be made up of six switching elements and six reflux diodes antiparallelly connected to each switching element. The SiC semiconductor device 12 according to any one of the embodiments 1 to 3 described above and a modification example thereof is applied to at least one of the switching element and the reflux diode of the main conversion circuit 201. Six switching elements are connected two by two in series to constitute upper and lower arms, and each pair of the upper and lower arms constitutes each phase (U phase, V phase, and W phase) of a full-bridge circuit. Output terminals of the pair of the upper and lower arms, that is to say, three output terminals of the main conversion circuit 201 are connected to the load 300.

The main conversion circuit 201 includes a drive circuit (not shown) driving each switching element. The drive circuit generates a drive signal for driving the switching element of the main conversion circuit 201, and supplies the drive signal to a control electrode of the switching element of the main conversion circuit 201. Specifically, the drive circuit outputs a drive signal for making the switching element enter an ON state and a drive signal for making the switching element enter an OFF state to a control electrode of each switching element in accordance with a control signal from the control circuit 203 describe hereinafter. When the switching element is kept in the ON state, the drive signal is a voltage signal (ON signal) larger than threshold voltage of the switching element, and when the switching element is kept in the OFF state, the drive signal is a voltage signal (OFF signal) smaller than the threshold voltage of the switching element.

The control circuit 203 controls the switching element of the main conversion circuit 201 so that desired electrical power is supplied to the load 300. Specifically, the control circuit 203 calculates a time (ON time) at which each switching element of the main conversion circuit 201 should enter the ON state based on the electrical power to be supplied to the load 300. For example, the control circuit 203 can control the main conversion circuit 201 by a pulse width modulation (PWM) control modulating the ON time of the switching element in accordance with the voltage to be outputted. Then, the control circuit 203 outputs a control command (control signal) to the drive circuit included in the main conversion circuit 201 so that the ON signal is outputted to the switching element which should enter the ON state and the OFF signal is outputted to the switching element which should enter the OFF state at each point of time. The drive circuit outputs the ON signal or the OFF signal as the drive signal to the control electrode of each switching element in accordance with the control signal.

A method of manufacturing the power conversion device 200 includes the following processes. The SiC semiconductor device 12 is manufactured by the manufacturing method descried in the above embodiments 1 to 3 or a modification example thereof. The main conversion circuit 201 including this SiC semiconductor device 12 is formed. The control circuit 203 is formed. The power conversion device 200 is thereby formed. In forming the main conversion circuit 201, as illustrated in FIG. 14, for example, the drain electrode 9 of the SiC semiconductor device 12 is bonded to the lead frame 14a via the solder 13, and the source electrode 8 is bonded to the lead frame 14b via the wire 15.

According to the present embodiment 4, the SiC semiconductor device 12 according to any one of the embodiments 1 to 3 is used as at least one semiconductor device constituting the main conversion circuit 201. Accordingly, a defect caused by stress from surrounding members in the switching operation can be suppressed while an unexpected negative influence caused by stress in assembling the SiC semiconductor device 12, for example, is suppressed. Reliability of the main conversion circuit 201 is thereby increased. Thus, reliability of the power conversion device 200 can be increased.

Described in the present embodiment 4 is the example of applying the SiC semiconductor device 12 to the three-phase inverter with two levels. However, the present embodiment 4 is not limited thereto, but can be applied to various power conversion devices. Described in the present embodiment 4 is the power conversion device with two levels, but a power conversion device with three levels or a multilevel power conversion device may also be applied. When electrical power is supplied to a single phase load, the power conversion device described above may be applied to a single-phase inverter. When electrical power is supplied to a direct current load, for example, the power conversion device described above can be applied to a DC/DC converter or an AC/DC converter.

The power conversion device according to the present embodiment 4 can be used not only in the case where the load described above is the electrical motor but can be used as a power source device of an electrical discharge machine, a laser beam machine, an induction heat cooking machine, or a non-contact power supply system, and further can also be used as a power conditioner of a solar power generation system or an electricity storage system, for example.

Each embodiment and each modification example can be arbitrarily combined, or each embodiment and each modification example can be appropriately varied or omitted.

### EXPLANATION OF REFERENCE SIGNS

1 SiC substrate, 1a reference surface, 6 gate electrode, 6a second upper surface, 6b first electrode part, 6c second electrode part. 7 interlayer insulating film, 7a first upper surface, 7b protrusion part, 7c connection part, 7d lower part, 7e second side surface, 7f first side surface, 7g curved part, 7h straight part, 7i connection part, 12 SiC semiconductor device, 201 main conversion circuit, 203 control circuit.

1. A semiconductor device, comprising:
a semiconductor substrate;
an electrode, at least a part of which protrudes to an upper side from a reference surface of the semiconductor substrate; and
an insulating film covering the reference surface of the semiconductor substrate and the electrode, wherein
the insulating film includes a first upper surface and a protrusion part protruding from the first upper surface corresponding to the reference surface of the semiconductor substrate and the at least the part of the electrode protruding from the reference surface, respectively, and
h1/h2, which is a ratio of h1 as a distance from the reference surface of the semiconductor substrate to a connection part connecting the first upper surface of the insulating film and a surface of the protrusion part to h2 as a distance from the reference surface of the semiconductor substrate to a second upper surface of the electrode, is equal to or larger than 1 and equal to or smaller than 1.5.

2. The semiconductor device according to claim 1, wherein
the electrode is wholly disposed on an upper side of the reference surface of the semiconductor substrate.

3. The semiconductor device according to claim 1, wherein
the electrode includes:
a first electrode part protruding from the reference surface of the semiconductor substrate; and
a second electrode part provided in a trench provided to the reference surface of the semiconductor substrate.

4. The semiconductor device according to claim 1, wherein
a ratio of an angle between the reference surface of the semiconductor substrate and a second side surface of a lower part of the insulating film on a lower side of the first upper surface to an angle between the reference surface of the semiconductor substrate and a first side surface of the protrusion part of the insulating film is equal to or larger than one.

5. The semiconductor device according to claim 1, wherein
an outer edge of the protrusion part includes a curved part in a cross section, and
a connection part between a straight part and the curved part in a cross section of an upper surface of the protrusion part is located immediately above an end portion of the electrode or immediately above an outer side of the end portion.

6. The semiconductor device according to claim 1, wherein
a material of the semiconductor device includes wide bandgap semiconductor.

7. A power conversion device, comprising:
a main conversion circuit including the semiconductor device according to claim 1, converting electrical power which has been input, and outputting the electrical power; and
a control circuit outputting a control signal for controlling the main conversion circuit to the main conversion circuit.
